(19) United States
(12) Patent Application Publication
(10) Pub. No.: US 2025/0364478 A1
(43) Pub. Date: Nov. 27, 2025

(54) DIE BONDING APPARATUS AND DIE POSITIONING METHOD USING THE DIE BONDING APPARATUS

(71) Applicant: ETEL S.A., Môtiers (CH)

(72) Inventor: Willson Sudarsandhari Shibani, Neuchâtel (CH)

(21) Appl. No.: 19/208,616

(22) Filed: May 15, 2025

(30) Foreign Application Priority Data
May 27, 2024 (EP) 24178178.0

(51) Int. Cl. H01L 23/00

(52) U.S. Cl. CPC H01L 24/74; H01L 24/80; H01L 2224/74; H01L 2224/80127; H01L 2224/8018; H01L 2224/80895; H01L 2924/40

(57) ABSTRACT

A die bonding apparatus including a linear motor and a carriage, the carriage including a bond-head configured to pick up a die and a camera configured to detect a target location for positioning the die and for measuring an alignment error between an optical axis of the camera and the target location. A central axis of the bond-head and the optical axis are distant from each other by a first distance. The apparatus includes a linear encoder with an encoder scale, first and second encoder heads mounted on the carriage, and a controller arranged to move the carriage as a function of values read by the first and second encoder heads to align the bonding head with the target location. The first and second encoder heads are distant from each other by a second distance corresponding to the first distance plus an alignment error.

### CROSS REFERENCE TO RELATED APPLICATIONS

This application claims benefit to European Patent Application No. EP 24178178.0, filed on May 27, 2024, which is hereby incorporated by reference herein

### FIELD

The present invention relates to the field of semiconductors and to a die bonding method for accurate positioning of a die before bonding and a die bonding apparatus for carrying out the die bonding method.

### BACKGROUND

Die bonding is extensively used for attaching or bonding a semiconductor chip, also known as a die, onto a substrate or a package. Die bonding can be performed using various techniques, including wire bonding, flip chip bonding and adhesive bonding. Die bonding plays a crucial role in creating the electrical connections necessary for the functionality of semiconductor devices. Precise positioning of dies is a fundamental aspect of semiconductor manufacturing to achieve optimal electrical performance, functionality, reliability and consistency in the final semiconductor devices.

Conventional die bonding systems, as shown in FIGS. 1 to 1c, comprise a carriage C comprising a bond-head BH and a down-looking camera DLC to be able to measure the position of the pads on the PCB for increased die placement accuracy. The down-looking camera DLC and the bond-head BH are attached to the carriage C at a fixed distance D as shown in FIG. 1. The carriage C is slidably engaged with rails to move along an encoder scale ES. The movements of the carriage C are measured with a single encoder head EH mounted on the carriage C and arranged to move along and above the encoder scale ES. The distance D between the down-looking camera DLC and the bond-head BH is measured using the encoder and an up-looking camera ULC while the carriage C is moved to search for the central axis of the bond-head BH and the optical axis of the camera DLC. The down-looking camera DLC is used to measure on the PCB the exact location of the pads onto which the die must be bonded. The camera DLC measures an alignment error ΔX between a target location TP and the optical axis of the down-looking camera DLC as shown in FIG. 1a. The carriage C is then moved by a distance D+ΔX so that the bond-head BH is above the target location to place the die as shown in FIGS. 1b and 1c.

The placement accuracy of these systems is not optimal as different placement errors may occur. In particular, the heat generated by the motors causes the thermal expansion of the encoder scale over D+ΔX as well as the thermal expansion of the carriage C which has a direct impact on the distance D between the bond-head and the camera. The scale engraving defects over D+ΔX has also a negative impact on the placement accuracy of these systems.

Yet, in hybrid bonding applications, dies are stacked on top of each other in packages using small copper-to-copper connections and therefore require the utmost placement accuracy of the dies down to the range of ±50 nm placement error.

Positioning systems comprising two encoder heads for compensating measurement errors due to thermal expansion of an encoder scale are also known. EP2636991A1 for example relates to a measuring machine provided with a system for compensating measurement errors due to thermal expansion of a scale of a linear transducer. Encoder heads are used to calculate a scale factor based on the distance between the two encoder heads and their respective readings to compensate for thermal expansion of the scale.

DE19919042A1 discloses a thermally compensated positioning system comprising a scale support supporting a scale and a carriage arranged to move along the scale and comprising two encoder heads spaced apart from each other by a predefined distance along the travel direction of the carriage. These two encoder heads are each configured to detect a reference mark and to feed to an evaluation unit two signals associated with that reference mark to compensate the encoder scale thermal expansion by using the relative distance between the two encoder heads that changes with temperature.

Other thermally compensated positioning systems comprising two encoder heads are disclosed for example in DE102021118091A1, DE102021118092A1, EP2527797A1 and EP3982088A1. In general, these positioning systems rely on multiple sensing units on the same scale to compensate for temperature or calibrate the scale. Scale mapping is usually used for thermal expansion compensation which is tedious and time consuming.

### SUMMARY

In an embodiment, the present disclosure provides a die bonding apparatus comprising a linear motor and a carriage arranged to be driven by the linear motor along a traveling direction, the carriage comprising a bond-head configured to pick up a die and a camera configured to detect a target location for positioning the die and for measuring an alignment error between an optical axis of the camera and the target location. A central axis of the bond-head and the optical axis of the camera are distant from each other along the traveling direction by a first distance. The die bonding apparatus further comprises a linear encoder comprising an encoder scale extending along the travel direction of the carriage, first and second encoder heads mounted on the carriage, and a controller arranged to move the carriage as a function of values read by respective encoder heads of the first and second encoder heads to align the bonding head with the target location. The first and second encoder heads are distant from each other along the traveling direction by a second distance corresponding to the first distance plus an alignment error between the first and second encoder heads and the central axis of the bond-head and the optical axis of the camera, respectively.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic view of a die bonding apparatus according to the prior art;

FIG. 1a, FIG. 1b and FIG. 1c show a sequence of movements for placing a die at a target location using the die bonding apparatus of FIG. 1;

FIG. 2 shows a schematic view of a die bonding apparatus according to an embodiment of the present disclosure;

FIG. 2a, FIG. 2b and FIG. 2c show a sequence of movements of a method, according to an embodiment of the present disclosure, for placing a die at a target location using the die bonding apparatus of FIG. 2,

FIG. 3 shows a schematic view of a bonding apparatus according to an embodiment of the present disclosure, and

FIG. 4 shows a schematic view of a die bonding apparatus according to an embodiment of the present disclosure.

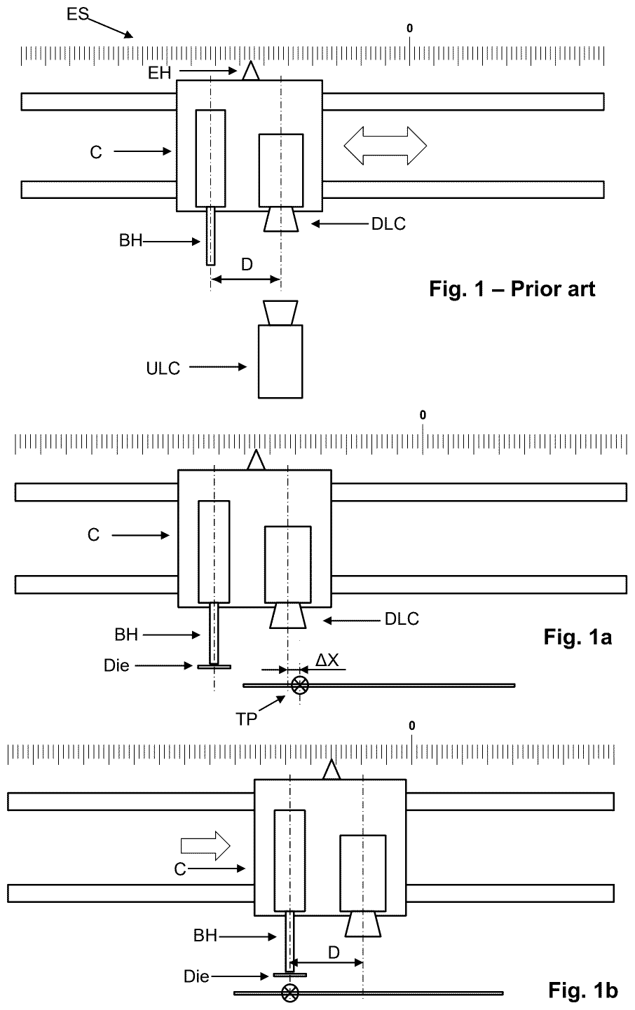

### DETAILED DESCRIPTION

In an embodiment, the present disclosure provides a die bonding apparatus and a die positioning method for accurate positioning of the die before bonding which are exempt of the above limitations.

More particularly, an embodiment of the present disclosure provides a die bonding apparatus and method for highly accurate positioning of dies down to the range of ±50 nm placement error, which makes the die bonding apparatus and method particularly suited for hybrid bonding applications.

An embodiment of the present disclosure provides a die positioning method wherein the die placement is insensitive to thermal expansion notably of the encoder scale.

An embodiment of the present disclosure provides a die positioning method wherein the die placement is insensitive to scale engraving defects.

The foregoing advantages are achieved notably by a die bonding apparatus comprising a linear motor, a carriage arranged to be driven by the linear motor along a traveling direction, a linear encoder comprising an encoder scale extending along the travel direction of the carriage, at least a first and a second encoder heads mounted on the carriage, and a controller arranged to move said carriage as a function of the values read by respective first and second encoder heads to align the bonding head with a target location. The carriage comprises a bond-head configured to pick up a die and a camera configured to detect the target location for positioning the die and for measuring an alignment error between the optical axis of the camera and said target location. The central axis of the bond-head and the optical axis of the camera are distant from each other along the traveling direction by a first distance. The first and second encoder heads are distant from each other along said traveling direction by a second distance corresponding to said first distance and an offset corresponding to an alignment error between said first and second encoder heads and the central axis of the bond-head and the optical axis of the camera respectively.

In an embodiment, the first and second encoder heads are aligned with the central axis of the bond-head and the optical axis of the camera respectively with an alignment error.

In an embodiment, the central axis of the bonding head intersects the center of the die when carried by said bonding head for die positioning on said target location.

In an embodiment, the die bonding apparatus further comprises a transverse beam, and two additional motion axes slidably engaged with said transverse beam and extending orthogonally thereof. The carriage is slidably mounted along the transverse beam. The linear encoder is a 1Dplus encoder comprising a linear scale having an incremental track and an additional track, a first and a second set of encoder heads arranged in correspondence with respectively the bond-head and the camera of the carriage. Each set of encoder heads comprises a Y-encoder head arranged to scan the incremental track and a least one X-encoder head arranged to scan the additional track for position correction of the transverse beam using said additional motion axes.

In an embodiment, each set of encoder heads comprises two X-encoder heads for angular correction of the bond-head and the camera using the additional motion axes.

In an embodiment, wherein said X-encoder heads of said first and second sets of encoder heads are arranged on both sides of respective bond-head and camera.

In an embodiment, the Y-encoder head of said first and second sets of encoder heads are aligned with the central axis of the bond-head and the optical axis of the camera respectively with an alignment error.

Another aspect of the present disclosure relates to a die positioning method using the die bonding apparatus according to any of the above described embodiments, wherein the method comprises the following steps:
a) finding with the camera of the carriage a target location for positioning the die,
b) measuring or recording an alignment error between the camera optical axis and said target location,
c) recording a difference between said first and second distances,
d) recording a position of the carriage with the first encoder head,
e) aligning the bond-head with said target location by moving the carriage as a function of:
   i) the outputs of the first and second encoder heads,
   ii) said recorded difference, and optionally said alignment error, and
f) actuating the bond-head in the Z-direction to place the die at said target location.

In an embodiment, the die positioning method comprises the steps of:
performing micro-alignments to reduce as much as possible the alignment error preferably below 10 nm, according to the feedback of the camera, and
moving the carriage to position the second encoder head at the position recorded by the first encoder head with an offset corresponding to the recorded difference between the first and second distances.

In an embodiment, the die positioning method comprises the steps of:
recording the alignment error between the camera optical axis and said target location, and
moving the carriage to position the second encoder head at the position recorded by the first encoder head with an offset combining the alignment error and the recorded difference between the first and second distances.

In an embodiment, the die bonding apparatus further comprises an up-looking camera placed below the target location and orientated to face the carriage. The die positioning method further comprises a calibration step performed prior to initiating the die placement at the target location. The calibration step comprises:
driving the carriage to move the camera and the bond-head above the up-looking camera to enable the latter to measure the first distance, and
further driving the carriage in the same direction such that the first and second encoder heads move across a reference mark of the encoder scale to measure the second distance in order to determine the encoder heads alignment error as a function of the measured first distance.

In an embodiment, an offset value between the central axis of the bond-head and the center of the die carried by said bond-head is measured using the up-looking camera. The offset value is used to correct the position of the carriage for accurate positioning of the die at the target location independently of the amplitude of the offset value.

An aspect of the present disclosure relates to a die positioning method using the die bonding apparatus, wherein the method comprises the following steps:
finding with the camera a target location for positioning the die,
recording a misalignment between the camera optical axis and said target location,
moving the carriage as a function of the signal outputs acquired by respective first and second said first and second sets of encoder heads to align the bond-head along the X-Y direction and around the Z-axis with said target location, and
actuating the die bond-head in the Z-direction to place the die at said target location.

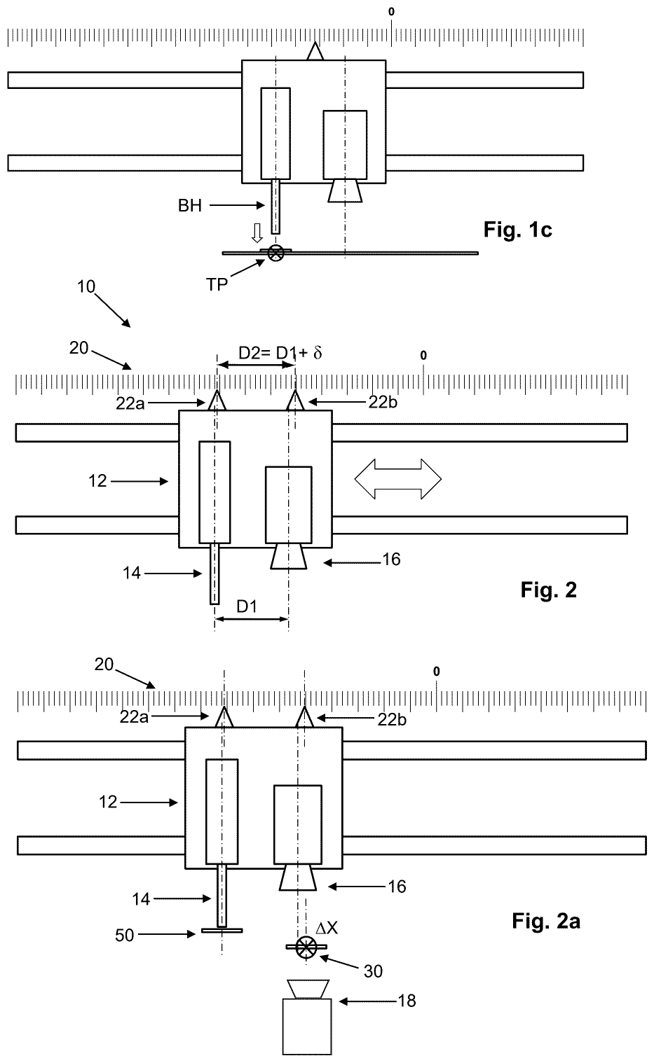

With reference to the embodiment illustrated in FIG. 2, the die bonding apparatus 10 comprises a linear motor, and a carriage 12 arranged to be driven by the motor along a traveling direction. The carriage 12 comprises a bond-head 14 configured to pick up a die 50 (FIG. 2a) and a first camera 16 configured detect a target location 30 for positioning the die 50. The camera 16 and the bond-head 14 are mounted on the carriage 12 with a first distance D1 between the optical axis of the camera 16 and the central axis of the bond-head 14 along the travel direction of the carriage 12.

The die bonding apparatus 10 further comprises a linear encoder having a scale 20 extending along the travel direction of the carriage 12, a first and a second encoder head 22a, 22b mounted on the carriage 12 and a controller configured to move the carriage 12 as a function of the values read by respective first and second encoder heads 22a, 22b to align the die 50 with the target location 30. The first and second encoder heads 22a, 22b are separated from each other along the travel direction of the carriage 12 by a second distance D2 as shown in FIG. 2.

In a preferred embodiment, the two encoder heads 22a, 22b are positioned as close as possible in alignment with respective camera optical axis and the bond-head central axis. There is however always encoder heads alignment error δ with respective camera 16 and bond-head 14 which must be taken into account for the utmost accurate positioning of the die. The second distance D2 between the two encoder heads 22a, 22b corresponds therefore to the first distance D1 and an offset corresponding to the encoder heads alignment error δ as illustrated in FIG. 2.

As explained above, the linear encoder is sensitive to thermal expansion induced in particular by the heat generated by the motors. The encoder scale 20 generally expands in its longitudinal direction when the bonding apparatus 10 is in operation which induces a measurement error on the scale. The first distance D1 between the optical axis of the camera 16 and the central axis of the bond-head 14 can also vary according to the thermal expansion of the carriage 12. The scale 20 can also have engraving defects. All these parameters must be taken into account for the utmost accurate placement of the die 50 at the target location 30.

Advantageously, the die placement by the die positioning method described subsequently is insensitive to these parameters.

A calibration step is needed prior to initiating the die placement to measure the first and second distances D1 and D2 and to determine the encoder heads alignment error δ.

In this regard, the die bonding apparatus 10 further comprises a second camera 18, as shown in FIG. 2a, which is placed below the target location 30 and orientated to face the carriage 12. The latter is driven to move the first camera 16 and the bond-head 14 above the second camera 18 to enable the latter to measure the first distance D1. The carriage 12 is then further driven in the same direction such that the first and second encoder heads 22a, 22b move across the reference mark “0” of the encoder scale 20 to measure the second distance D2 in order to determine the encoder heads alignment error δ as a function of the measured first distance D1.

Referring to FIG. 2a, once the calibration step is completed, the die positioning method consists in driving the carriage 12 to align the optical axis of the first camera 16 with the target location 30. More particularly, the camera 16 measures an alignment error ΔX between the camera optical axis and the target location 30. The signal output of the camera 16 is sent to the motor controller to drive the motor so as to perform several micro-alignments to reduce as much as possible the alignment error ΔX preferably below 10 nm.

The first encoder head 22a then reads the position Pl on the encoder scale 20. The motor controller then drives the motor to move the carriage 12 as a function of signal outputs of the first and second encoder heads 22a, 22b and according to the encoder heads alignment error δ such that the second encoder head 22b is moved to the position P1-δ. The central axis of the bond-head 14 is thus aligned with the target location 30 with an accuracy below 10 nm. The bond-head 14 is then actuated in the Z-direction to bond the die 50 on top of another die with the utmost accuracy.

It is thus readily apparent that any thermal expansion and/or any engraving defects of the encoding scale 20 does not have any repercussion on the placement accuracy of the die 50 since the discrete position P1 at which the second encoder head 22b is brought remains at a fixed point independently of the thermal expansion/engraving defects parameters. This also highlights the need to make the encoder heads alignment error δ as small as possible so that the target position P1-δ of the second encoder head 22b is as close as possible to the position P1.

In an embodiment, the die positioning method consists in aligning the bond-head 14 with the target location 30 without performing the above step of micro-alignments of the camera axis. Instead, the alignment error ΔX between the camera axis and the target location 30 is first recorded and the motor controller drives the carriage 12 as a function of the signal outputs of respective first and second encoder heads 22a, 22b and according to the encoder heads alignment error δ such that the second encoder 22b is moved to the position P1-δ+ΔX. The die positioning method according to this embodiment has the advantage to be faster at the expense of the accuracy. Indeed, the accuracy obtained is the local accuracy over ΔX meaning that any thermal expansion and/or any scale engraving error occurring over ΔX would directly impact the placement accuracy of the die.

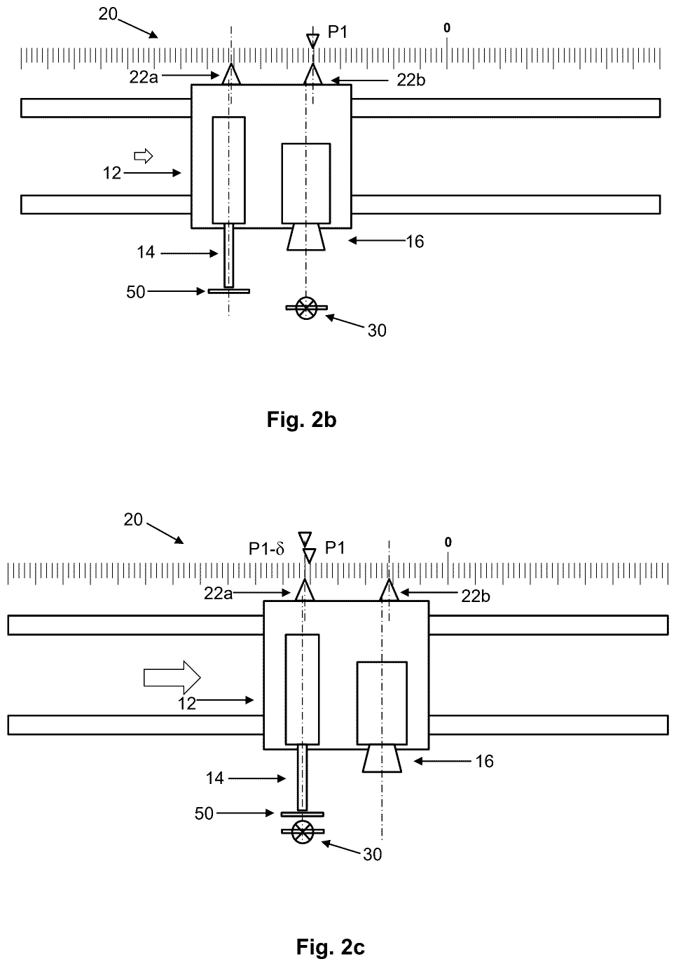

According to an embodiment schematically illustrated in FIG. 3, the camera 16 and the bond-head 14 are mounted on the carriage 12 with a distance D1 between the camera optical axis and the bond-head central axis along the travel direction of the carriage 12. The first and second encoder heads 22a, 22b are mounted on the carriage 12 such that they are offset with respect to the camera optical axis and the bond-head central axis along the travel direction. The distance D2 between the encoder heads 22a, 22b remains however the same distance as the first distance D1 with an offset corresponding to an alignment error δ.

The placement of the die 50 at the target location 30 can be however less accurate according to this embodiment considering that the portion of the carriage 12 within the distance D1 can have a slightly different behavior compared to the portion of the carriage 12 within the distance D2 in terms of thermal expansion when subjected to the heat of the motor.

In a preferred embodiment, an offset value between the central axis of the bond-head 14 and the center of the die 50 carried by the bond-head 14 for die positioning at the target location 30 is measured using the up-looking camera 18. The measured offset value is then fed to the controller of the motor to correct the position of the carriage 12. This ensures accurate positioning of the die 50 in case the center of the latter is misaligned with the bond-head central axis.

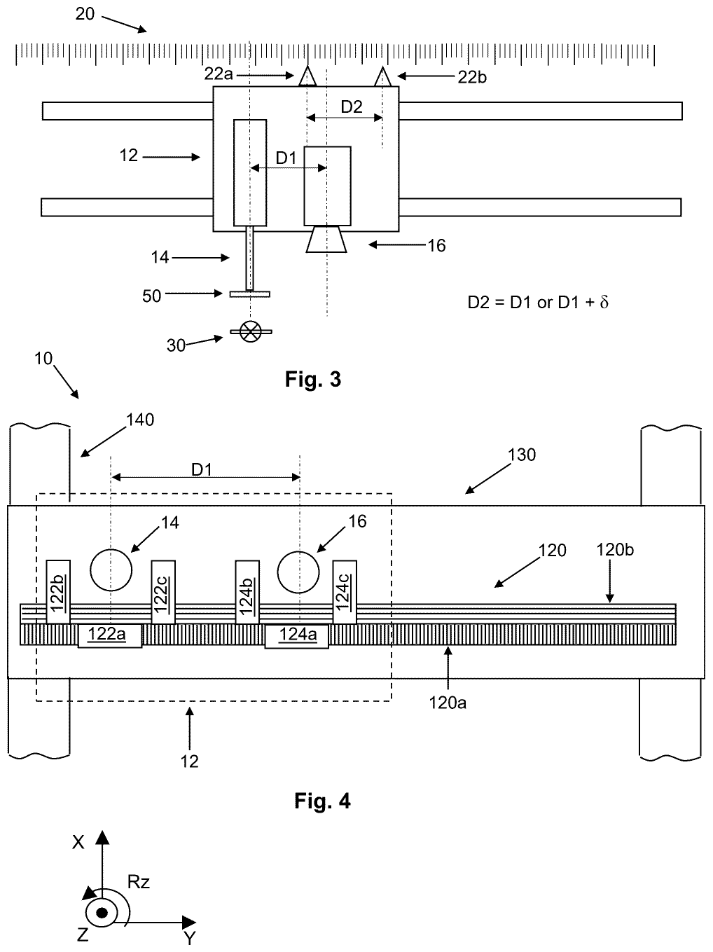

According to an embodiment schematically illustrated in FIG. 4, the die bonding apparatus 10 comprises a Y-beam 130 slidably engaged with two motion axes 140 in the X direction and a carriage 12 mounted to move along the Y-beam and comprising a bond-head 14, a camera 16 and two set of encoder heads arranged to read a 1Dplus scale 120 featuring an incremental track 120a along the Y-direction as well as additional track 120b that provides the information required for compensation in the perpendicular direction and for angular correction.

The first set of encoder heads comprises a Y-encoder head 122a arranged on the incremental track 120a of the 1Dplus scale 120 and two X-encoder heads 122b, 122c arranged on the additional track 120b on both sides of the bond-head 14. The second set of encoder heads comprises a Y-encoder head 124a arranged on the incremental track 120a of the 1Dplus scale 120 and two X-encoder heads 124b, 124c arranged on the additional track 120b on both sides of the camera 16.

The alignment of the bond-head 14 along the Y-direction is performed by moving the carriage 12 according to the die positioning method described in relation with the embodiments of FIGS. 2 to 2c using the Y-encoder head 122a, 124a of respective first and second sets. The two X-encoder heads 122b, 122c, 124b, 124c are arranged to compensate for alignment errors in the X-direction and angular error in the Rz-direction using motion axes 140.

While embodiments of the present disclosure have been illustrated and described in detail in the drawings and foregoing description, such illustration and description are to be considered illustrative or exemplary and not restrictive. It will be understood that changes and modifications can be made by those of ordinary skill within the scope of the appended claims. For example, the die positioning method using the die bonding apparatus can be adapted for a 6-DOF positioning system with multiples encoders.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### REFERENCE LIST

Die bonding apparatus 10
Carriage 12
Bond-head 14
First Camera 16
Second camera 18
Encoder scale 20
First and second encoder heads 22a, 22b
1Dplus encoder scale 120
Incremental track 120a
Additional track 120b
First encoder assembly:
   Y-encoder head 122a
   Two X-encoder heads 122b, 122c
Second encoder assembly:
   Y-encoder head 124a
   Two X-encoder heads 124b, 124c
Y-beam 130
Motion axes 140
Target location 30
Camera alignment error ΔX with the target location
Encoder heads alignment error δ with respective camera and bond-head
Distance between camera and the bond head D1
Distance between the two encoder heads D2
Die 50

1. A die bonding apparatus comprising:
a linear motor;
a carriage arranged to be driven by the linear motor along a traveling direction, the carriage comprising a bond-head configured to pick up a die and a camera configured to detect a target location for positioning the die and for measuring an alignment error between an optical axis of the camera and the target location, wherein a central axis of the bond-head and the optical axis of the camera are distant from each other along the traveling direction by a first distance;
a linear encoder comprising an encoder scale extending along the travel direction of the carriage;
first and second encoder heads mounted on the carriage; and
a controller arranged to move the carriage as a function of values read by respective encoder heads of the first and second encoder heads to align the bonding head with the target location,
wherein the first and second encoder heads are distant from each other along the traveling direction by a second distance corresponding to the first distance plus a second alignment error between the first and second encoder heads and the central axis of the bond-head and the optical axis of the camera, respectively.

2. The die bonding apparatus according to claim 1, wherein the first and second encoder heads are aligned with the central axis of the bond-head and the optical axis of the camera, respectively, with the second alignment error.

3. The die bonding apparatus according to claim 1, wherein the central axis of the bond-head intersects a center of the die when carried by the bond-head for die positioning on the target location.

4. The die bonding apparatus according to claim 1, further comprising:
a transverse beam;
two motion axes slidably engaged with the transverse beam and extending orthogonally thereof,
wherein the carriage is slidably mounted along the transverse beam, and
wherein the linear encoder is a 1Dplus encoder comprising a linear scale having an incremental track and an additional track; and
a first set of encoder heads and a second set of encoder heads arranged in correspondence with respectively the bond-head and the camera of the carriage, each set of encoder heads comprising a Y-encoder head of the first and second encoder heads arranged to scan the incremental track and a least one X-encoder head of the first and second encoder heads arranged to scan the additional track for position correction of the transverse beam using the motion axes.

5. The die bonding apparatus according to claim 4, wherein each set of encoder heads comprises two X-encoder heads for angular correction of the bond-head and the camera.

6. The die bonding apparatus according to claim 5, wherein the X-encoder heads of the first and second sets of encoder heads are arranged on both sides of, respectively, the bond-head and the camera.

7. The die bonding apparatus according to claim 4, wherein the Y-encoder head of the first and second sets of encoder heads are aligned with the central axis of the bond-head and the optical axis of the camera, respectively, with the second alignment error.

8. A die positioning method using the die bonding apparatus according to claim 1, wherein the method comprises:
finding with the camera of the carriage a target location for positioning the die;
measuring or recording the alignment error between the camera optical axis and the target location;
recording a difference between the first distance and the second distance;
recording a position of the carriage with the first encoder head;
aligning the bond-head with the target location by moving the carriage as a function of:
outputs of the first and second encoder heads, and
the recorded difference; and
actuating the bond-head in a Z-direction to place the die at the target location.

9. The die positioning method according to claim 8, comprising:
performing micro-alignments to reduce the alignment error below 10 nm, according to feedback of the camera, and
moving the carriage to position the second encoder head at the position recorded by the first encoder head with an offset corresponding to the recorded difference.

10. The die positioning method according to claim 8, comprising:
recording the alignment error between the camera optical axis and the target location; and
moving the carriage to position the second encoder head at the position recorded by the first encoder head with an offset combining the recorded difference and the alignment error.

11. The die positioning method according to claim 8, wherein the die bonding apparatus further comprises an up-looking camera placed below the target location and orientated to face the carriage, and
wherein a calibration step is performed prior to initiating the die placement, the calibration step comprising:
driving the carriage in a driving direction to move the camera and the bond-head above the up-looking camera to enable the up-looking camera to measure the first distance, and
further driving the carriage in the driving direction such that the first and second encoder heads move across a reference mark of the encoder scale to measure the second distance in order to determine the second alignment error as a function of the measured first distance.

12. The die positioning method according to claim 11, wherein an offset value between the central axis of the bond-head and the center of the die carried by the bond-head is measured using the up-looking camera, and wherein the offset value is used to correct the position of the carriage for accurate positioning of the die at the target location independently of an amplitude of the offset value.

13. A die positioning method using the die bonding apparatus according to claim 4, the method comprising:
finding with the camera the target location for positioning the die,
recording a misalignment between the camera optical axis and the target location,
moving the carriage as a function of signal outputs acquired by respective first and second sets of encoder heads to align the bond-head along an X-Y direction and around a Z-direction with the target location, and
actuating the bond-head in the Z-direction to place the die at the target location.

14. The die positioning method according to claim 8, wherein the bond-head is aligned with the target location by moving the carriage as a further function of the alignment error.
